(19) United States
(12) Patent Application Publication
(10) Pub. No.: US 2014/0353149 A1
(43) Pub. Date: Dec. 4, 2014

(54) TUNNEL MAGNETO-RESISTANCE ELEMENT MANUFACTURING APPARATUS

(71) Applicant: CANON ANELVA CORPORATION, Kawasaki-shi (JP)

(72) Inventors: Takuya SEINO, Kawasaki-shi (JP); Kazumasa NISHIMURA, Kawasaki-shi (JP); Koji TSUNEKAWA, Kawasaki-shi (JP); Eisaku WATANABE, Kawasaki-shi (JP); Shigeo KANEKO, Kawasaki-shi (JP)

(21) Appl. No.: 14/462,860

(22) Filed: Aug. 19, 2014

Related U.S. Application Data
(63) Continuation of application No. PCT/JP2013/003014, filed on May 10, 2013.

(30) Foreign Application Priority Data
Aug. 10, 2012 (JP) 2012-178207
Dec. 28, 2012 (JP) 2012-287202

(51) Int. Cl. H01L 21/67

(52) U.S. Cl. CPC H01L 21/67184; H01L 21/67173
USPC 204/298.07; 204/298.25

(57) ABSTRACT

The present invention provides a TMR element manufacturing apparatus capable of reducing contamination of impurities in magnetic films. According to an embodiment of the present invention, a tunnel magneto-resistance element manufacturing apparatus includes: a load lock device to load and unload a substrate from and to an outside; a first substrate transfer device that is connected to the load lock device, at least one substrate process device being connected to the first substrate transfer device; a first evacuation unit provided in the first substrate transfer device; a second substrate transfer device that is connected to the first substrate transfer device, multiple substrate process devices being connected to the second substrate transfer device; and a second evacuation unit provided in the second substrate transfer device. At least one of the multiple substrate process devices connected to the second substrate transfer device is an oxidation device.

### CROSS-REFERENCES TO RELATED APPLICATIONS

This application is a continuation application of International Application No. PCT/JP2013/003014, filed May 10, 2013, which claims the benefit of Japanese Patent Application Nos. 2012-178207, filed Aug. 10, 2012 and 2012-287202, filed Dec. 28, 2012. The contents of the aforementioned applications are incorporated herein by reference in their entireties.

### TECHNICAL FIELD

The present invention relates to a tunnel magneto-resistance element manufacturing apparatus.

### BACKGROUND ART

In recent years, the magnetic random access memory (MRAM) has been drawing attention. The MRAM is an integrated magnetic memory in which semiconductor elements are formed with incorporation of a tunnel magneto resistance effect (TMR) technology. As TMR elements used in the MRAM, there are used an in-plane magnetized element in which the magnetic orientation of a magnetic free layer and a reference layer is magnetically reversed in a direction perpendicular to a layer stacking direction as described in Non Patent Document 1, and a perpendicular magnetized element in which the magnetic orientation of a magnetic free layer and a reference layer is magnetically reversed in the same direction as the layer stacking direction as described in Non Patent Document 2. Moreover, there has been reported a structure in which an oxide layer is formed on top of the magnetic free layer as described in Non Patent Document 3.

Besides the structures described in Non Patent Document 1 and Non Patent Document 2, the manufacturing of TMR elements widely uses a sputtering film deposition (hereinafter also simply referred to as sputter) method of sputtering a target made of a desired film deposition material to deposit a film on an opposed substrate (Patent Document 1).

### CITATION LIST

### Patent Document

Patent Document 1: International Patent Application Publication No. WO2012/086183

### Non Patent Document

Non Patent Document 1: Young-suk Choi et al., Journal of Appl. Phys. 48 (2009) 120214

Non Patent Document 2: D. C. Worledge et al., Appl. Phys. Lett. 98 (2011) 022501

Non Patent Document 3: Kubota et al., Journal of Appl. Phys. 111, 07C723 (2012)

### SUMMARY OF INVENTION

### Technical Problem

The aforementioned techniques, however, entail the following problems.

In the manufacturing method described in Patent Document 1, a structure is presented in which four kinds of materials of Ta, Ru, CoFeB and MgO are sputtered for perpendicular magnetized stacked films. Along with continued increases in density, the STT (Spin Transfer Torque)-MRAM stack structure becomes more complicated and a larger number of stacked films need to be formed. Specifically, such a structure is presented in Non Patent Document 2. In the case where many stacked films are deposited by sputter, a time for which the substrate stays in a single chamber needs to be shortened. Otherwise, the throughput becomes slow, the productivity is decreased, and consequently the costs for semiconductor devices are increased. To address this, what should be achieved are to sputter various kinds of materials while suppressing reductions in throughput and productivity and to carry out an annealing process for property improvement and an oxidation process for oxide film formation within short periods of time.

In addition, Patent Document 1 discloses the structure in which oxidation, heating and washing (etching) chambers and four sputter chambers each having three targets are connected to a substrate transfer chamber including a substrate introduction chamber. This apparatus has a problem that, if substrates are continuously carried into the transfer chamber from the substrate introduction chamber, the ultimate vacuum level of the transfer chamber is so deteriorated that impurities in the order of atomic layer are adsorbed onto the substrates in the transfer chamber. In addition, the apparatus also has a problem that such adsorption of impurities to the interface results in occurrence of a crystal defect and property degradation in a metal stacked film structure.

### Solution to Problem

The invention of the present application has been made in view of the aforementioned problems, and has an objective to provide a TMR element manufacturing apparatus capable of reducing contamination of impurities in magnetic films.

To solve the foregoing problems, a first aspect of the invention of the present application is a tunnel magneto-resistance element manufacturing apparatus including: a load lock device configured to load and unload a substrate from and to an outside; a first substrate transfer device that is connected to the load lock device, at least one substrate process device being connected to the first substrate; first evacuation means provided in the first substrate transfer device; and a second substrate transfer device that is connected to the first substrate transfer device, multiple substrate process devices being connected to the second substrate transfer device; and second evacuation means provided in the second substrate transfer device. At least one of the multiple substrate process devices connected to the second substrate transfer device is an oxidation device.

### Advantageous Effects of Invention

The present invention makes it possible to reduce contamination of impurities in magnetic films. Thus, in the formation of a magneto-resistance element structure requiring deposition of a larger number of stacked films, the occurrence of crystal defects and property degradation in a metal stacked film structure can be reduced, and therefore the throughput and productivity can be improved.

### BRIEF DESCRIPTION OF DRAWINGS

FIG. 1 is a diagram for explaining a TMR element manufacturing apparatus according to an embodiment of the present invention.

FIG. 2 is a diagram for explaining a TMR element manufacturing apparatus according to an embodiment of the present invention.

FIG. 3 is a diagram for explaining a TMR element manufacturing apparatus according to an embodiment of the present invention.

FIG. 4 is a diagram for explaining a TMR element manufacturing apparatus according to an embodiment of the present invention.

FIG. 5 is a diagram for explaining a TMR element manufacturing apparatus according to an embodiment of the present invention.

FIG. 6 is a diagram for explaining a TMR element manufacturing apparatus according to an embodiment of the present invention.

FIG. 7 is a flowchart for controlling gate valve operations and substrate transfer according to an embodiment of the present invention.

FIG. 8 is an explanatory diagram of an oxidation flow in the case of using a manufacturing apparatus according to an embodiment of the present invention.

FIG. 9 is an explanatory diagram of an oxidation flow in the case of using a manufacturing apparatus according to an embodiment of the present invention.

FIG. 10 is a diagram for explaining a sputtering device used in an embodiment of the present invention.

FIG. 11 is a diagram for explaining an oxidation device according to an embodiment of the present invention.

FIG. 12 is a diagram for explaining an oxidation device according to an embodiment of the present invention.

FIG. 13 is a diagram for explaining a control device used in a manufacturing apparatus according to an embodiment of the present invention.

### DESCRIPTION OF EMBODIMENTS

Hereinafter, regarding a manufacturing apparatus and the like of the present invention, embodiments of the present invention are described based on the drawings. In the following description, duplicate description for elements common to the embodiments is omitted.

### First Embodiment

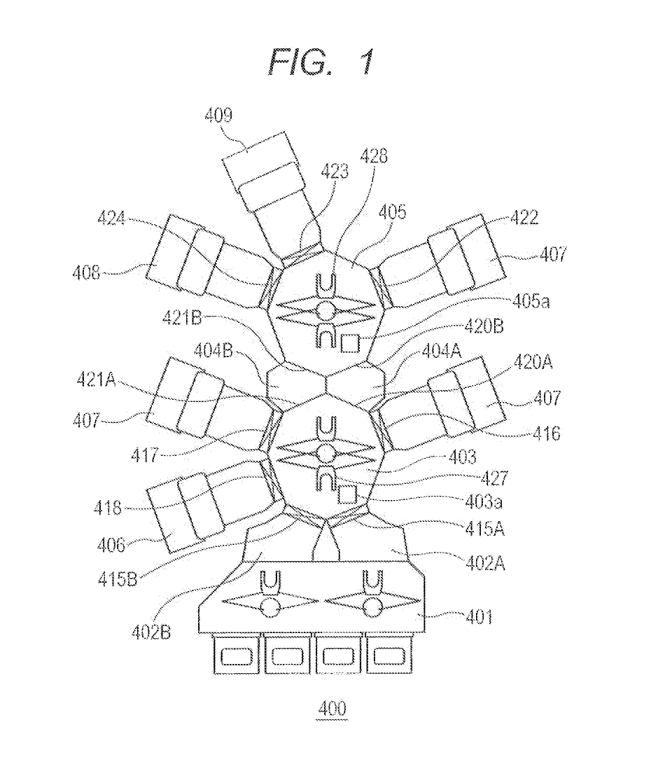

FIG. 1 illustrates an example of a structure of a TMR element manufacturing apparatus 400 according to the present embodiment. The manufacturing apparatus 400 includes: a transfer device 403 which includes a robot arm 427 and to which at least one substrate process device is connected; a transfer device 401 and unloading/loading chambers 402A, 402B to load a substrate into the transfer device 403 or unload a substrate completely processed; and a transfer device 405 which includes a robot arm 428 and to which multiple substrate process devices are connected. Moreover, the manufacturing apparatus 400 may include mount chambers 404A and 404B to load and unload the substrate from and to the transfer device 403 and the transfer device 405. The unloading/loading chambers 402A and 402B are what are called load lock (LL) chambers for loading and unloading a substrate from and to the outside of the manufacturing apparatus 400, and each include an evacuation device to evacuate the device to vacuum, and a gas introduction mechanism to bring the pressure in the device into atmospheric pressure. In addition, gate valves 415A, 415B are provided between the unloading/loading chambers 402A, 402B and the transfer device 403, respectively.

Evacuation devices 403a and 405a are connected to the transfer device 403 and the transfer device 405, respectively. The evacuation devices 403a and 405a evacuate the respective transfer devices to vacuum. Any type of evacuation device, such as a turbo-molecular pump or a cryopump, for example, which can obtain a vacuum level necessary in the present embodiment can be used as the evacuation devices 403a, 405a.

Note that it is preferable that the vacuum level inside the transfer device 405 be higher than the vacuum level inside the transfer device 403.

Gate valves are provided between the transfer device 403 and the transfer device 405. In the case where the mount chambers 404A, 404B are provided between the transfer device 403 and the transfer device 405, the gate valves are provided at least either between the mount chambers 404A, 404B and the transfer device 405 or between the mount chambers 404A, 404B and the transfer device 403. Thus, the space in the transfer device 403 and the space in the transfer device 405 are isolated from each other, so that the transfer device 405 can keep a high vacuum level. The present embodiment employs a structure in which two mount chambers 404A and 404B are provided between the transfer device 403 and the transfer device 405, and gate valves 420A, 420B, 421A, 421B are provided between the transfer device 403, the mount chambers 404A, 404B and the transfer device 405. This structure is capable of more securely maintaining the transfer device 405 at a high vacuum level. In addition, the gate valves 420A, 420B and the gate valves 421A, 421B located between the transfer device 403 and the transfer device 405 are not simultaneously opened/closed, which can more inhibit vacuum deterioration which may occur in loading the substrate to the transfer device 405. This makes it possible to maintain the vacuum level in the transfer device 405 more stably and preferably.

Moreover, the manufacturing apparatus 400 according to the present embodiment further includes an etching device 406 to remove a natural oxide film and impurities attached to a substrate surface before the formation of TMR elements, and includes sputter devices (5PVD) 407 each including five sputtering target cathodes as sputter devices to form various kinds of metal films of the TMR elements. The manufacturing apparatus 400 further includes a sputter device (2PVD) 408 including two sputtering target cathodes, and an oxidation device 409 to oxidize a metal film. The etching device 406 is connected to the transfer device 403, and the sputter devices (5PVD) 407 are connected to the transfer device 403 and the transfer device 405. Moreover, the sputter device (2PVD) 408 is connected to the transfer device 405. The connection of the sputter devices (5PVD) 407 and the sputter device (2PVD) 408 as sputter devices each including too or more sputtering cathodes to the transfer device 403 and the transfer device 405 can be changed appropriately depending on processes of substrate treatments to be performed. The oxidation device 409 is connected to the transfer device 405.

A gate valve 418 is provided between the etching device 406 and the transfer device 403, and gate valves 416, 417 are provided between the sputter devices (5PVD) 407 and the transfer device 403. Moreover, a gate valve 422 is provided between the sputter device 407 and the transfer device 405, a gate valve 424 is provided between the sputter device (2PVD) 408 and the transfer device 405, and a gate valve 423 is provided between the oxidation device 409 and the transfer device 405.

In order to inhibit impurity adsorption to an interface of a metal stacked film due to vacuum deterioration, the manufacturing apparatus 400 according to the present embodiment is provided with the transfer device 405 connected via the gate valves to the transfer device 403 in contact with the LL chambers through which substrates are to be loaded and unloaded. Thus, the transfer device 405 can be maintained at an ultrahigh vacuum level. The oxidation device 409 is connected to the transfer device 405. This structure is capable of inhibiting impurity adsorption particularly in the formation or process of films which are to contribute to element properties, and therefore is capable of manufacturing TMR elements by inhibiting the occurrence of a crystal defect and property degradation in a metal stacked film structure. The manufacturing of TMR elements requires reduction in the impurity attachment to the substrate during the oxidation process. In the present embodiment, the oxidation device 409 is connected to the transfer device 405. The transfer device 405 is not directly connected to the LL chambers through which the substrate is loaded and unloaded from and to the outside, but the transfer device 405 is connected to the LL chambers via another transfer device (403). Thus, the vacuum level in the transfer device 405 itself can be enhanced, and the oxidation device 409 required to achieve a very high vacuum level is connected to the transfer device 405 in which an ultra-high vacuum is established. Consequently, even if film deposition is continuously performed on many substrates, the inside of the oxidation device 409 can be maintained at an ultra-high vacuum. Hence, the impurity adsorption to the substrate (the deposited film) can be reduced in the oxidation process in the manufacturing of TMR elements, as described above.

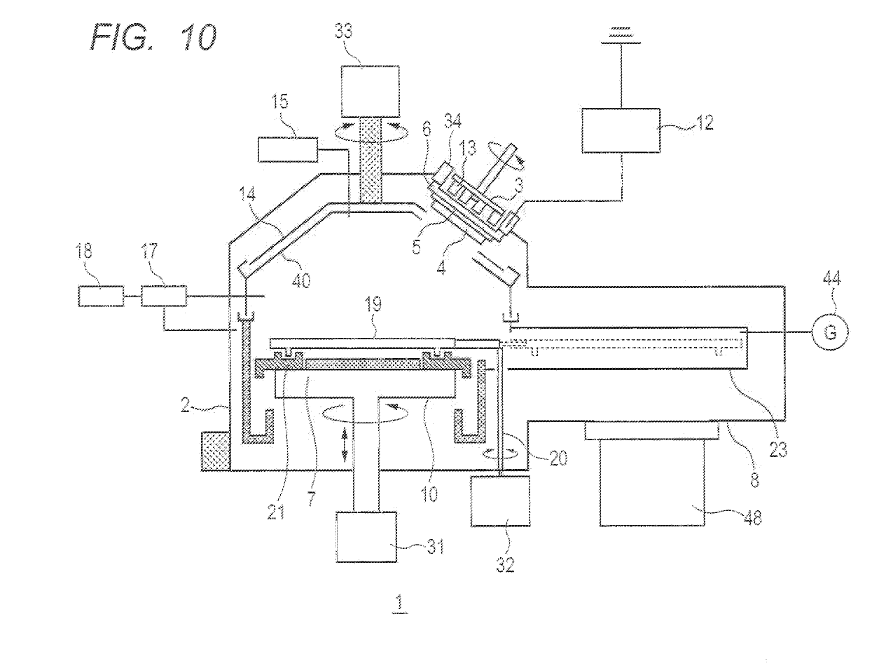

Here, using FIG. 10, description is provided for a sputtering device according to the present embodiment. A sputtering device 1 includes a process chamber 2 capable of producing a vacuum by evacuation, an evacuation chamber 8 provided adjacent to the process chamber 2 via an air outlet, and an evacuation device 48 to evacuate the process chamber 2 via the evacuation chamber 8. A target holder 6 to hold a target 47 with a back plate 5 interposed in between is provided inside the process chamber 2. A target shutter 14 is installed near the target holder 6 so as to shield the target holder 6. The target shutter 14 has a rotary shutter structure. The target shutter 14 includes a target shutter driving mechanism 33 to perform open and close operations of the target shutter 14.

Moreover, the process chamber 2 includes an inert gas introduction system 15 to introduce an inert gas (Ar or the like) into the process chamber 2, a reactant gas introduction system 17 to introduce a reactant gas (oxygen, nitrogen or the like), and a pressure gage 44 to measure the pressure inside the process chamber 2. Each of the introduction systems is connected to a gas feeder to feed the gas. Each introduction system includes a pipe to introduce the gas, a mass flow controller (MFC) to control a flow rate, and other parts, and is controlled by s control device (a control device illustrated in FIG. 13, for example).

The reactant gas introduction system 17 is connected to a reactant gas feeder (gets cylinder) 18 to feed the reactant gas. The reactant gas introduction system 17 includes a pipe to introduce the reactant gas, an MFC to control a flow rate of the reactant gas, and a valve and other parts to shut off and pass a gas flow. Incidentally, the reactant gas introduction system 17 may include a pressure reducing valve, a filter and the like if necessary. With this structure, the reactant gas introduction system 17 is capable of feeding the gas stably at a flow rate specified by the control device not illustrated.

An inner surface of true process chamber 2 is electrically grounded. The inner surface of the process chamber 2 between the target holder 6 and the substrate holder 7 is provided with a tube-form shield 40 which is electrically grounded. The evacuation chamber 8 connects the process chamber 2 and the evacuation device 48. Magnets 13 to implement magnetron sputtering sire provided behind the target 4. The magnets 13 are held by a magnet holder 3 and are rotatable by a magnet holder rotation mechanism not illustrated. A power supply 12 to apply power for sputtering discharge is connected to the target holder 6. In the present embodiment, the sputtering device 1 illustrated in FIG. 15 includes a DC power supply, but may include an RF power supply, instead.

The target holder 6 is insulated by an insulator 34 from the process chamber 2 at a ground potential. The back plate 5 provided between the target 4 and the target border 6 holds the target 4. The target shutter 14 is installed near the target holder 6 so as to cover the target holder 6. The target shutter 14 functions as a shield member to create a close state where the target holder 6 and the substrate holder 7 are shielded from each other and an open state where the target holder 6 and the substrate holder 7 are exposed to each other.

A ring-shaped shield member (also referred to as a “covering 21” below) is provided on a surface of the substrate holder 7 at an outer edge side (outer circumferential portion) outside a portion where to mount a substrate 10. The covering 21 prevents or reduces attachment of sputter particles onto any site other than a film deposition surface of the substrate 10 mounted on the substrate holder 7. The substrate holder 7 is provided with a substrate holder driving mechanism 31 to move the substrate holder 7 up and down and to rotate the substrate holder 7 at a predetermined speed. A substrate shutter 19 is arranged near the substrate 10 between the substrate holder 7 and the target holder 6. The shutter 19 is supported by a substrate shutter supporting member 20 so as to cover the surface of the substrate 10. A substrate shutter driving mechanism 32 inserts the shutter 19 between the target 4 and the substrate 10 (a close state) at a position near the surface of the substrate 10 by rotating and translating the substrate shutter supporting member 20. When the shutter 19 is inserted between the target 4 and the substrate 10, the substrate 10 and the target 4 are shielded from each ether. In addition, when the substrate shutter driving mechanism 32 operates to retreat the shutter 19 from between the target holder 6 (target 4) and the substrate holder 7 (substrate 10), the target holder 6 (target 4) and the substrate holder 7 (substrate 10) are exposed to each other (an open state). The substrate shutter driving mechanism 32 opens and closes the shutter 19 by driving in order to create the close state where the substrate holder 7 and the target holder 6 are shielded from each other and the open state where the substrate holder/and the target holder 6 are exposed to each other. In the open state, the shutter 19 is housed in a shutter housing portion 23. It is preferable that the shutter housing portion 23 as a location where the shutter 19 is to be retracted be provided within a conduit for an evacuation path leading to the evacuation device 48 for evaluation to a high vacuum level as illustrated in FIG. 15, because the device area can be made small.

### Second Embodiment

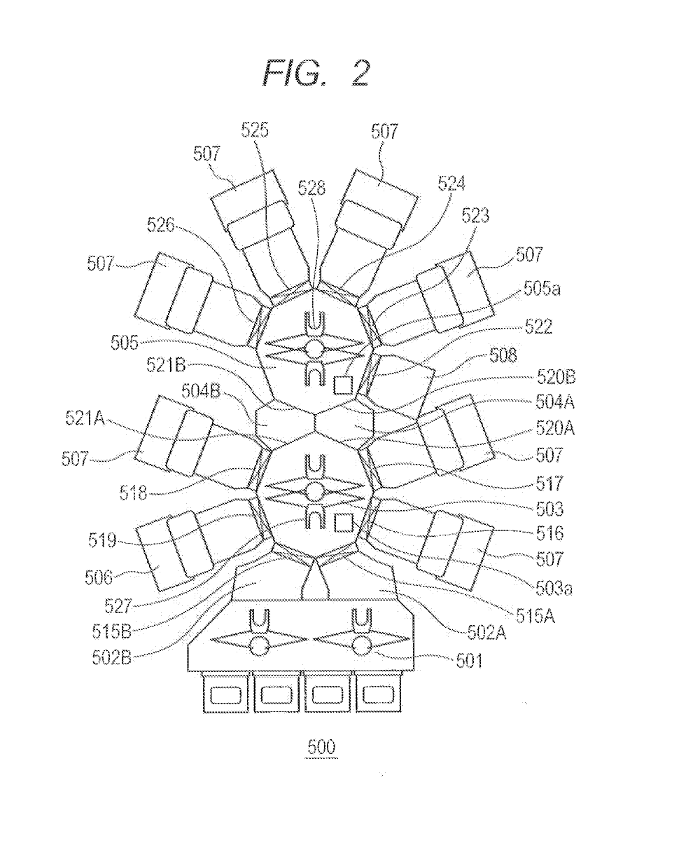

FIG. 2 illustrates an example of a structure of a TMR element manufacturing apparatus 500 according to the present embodiment. The manufacturing apparatus 500 includes: a transfer device 503 which includes a robot arm 527 and to which at leant one substrate process device is connected; a transfer device 501 and unloading/loading chambers 502A, 502B to load a substrate into the transfer device 503 or unload the substrate completely processed; a transfer device 505 which includes a robot arm 528 and to which multiple substrate process devices are connected; and mount chambers 504A and 504B to load and unload the substrate from and to the transfer device 503 and the transfer device 505. Evacuation devices 503a and 505a are connected to the transfer device 503 and the transfer device 505, respectively. The evacuation devices 503a and 505a evacuate the respective transfer devices to vacuum. Any type of evacuation device, such as a turbo-molecular pump or a cryopump, for example, which can obtain a vacuum level necessary in the present embodiment can be used as the evacuation devices 503a, 505a.

Moreover, gate valves 520B, 521B are provided between the mount chambers 504A, 504B and the transfer device 505, and also gate valves 520A, 521A are provided between the mount chambers 504A, 504B and the transfer device 503. The transfer device 505 is maintained at a high vacuum level. In addition, vacuum deterioration which occurs in loading the substrate to the transfer device 505 is more inhibited. The vacuum level in the transfer device 505 can be maintained more stably and preferably. Moreover, gate valves 515A, 515B are provided between the unloading/loading chambers 502A, 502B and the transfer device 503, respectively.

Further, the manufacturing apparatus 500 further includes an etching device 506 to remove a natural oxide film and impurities attached to a substrate surface before the formation of TMR elements, and includes sputter devices (4PvD) 507 each including four sputtering target cathodes as sputter devices to form various kinds of metal films of the TMR elements. The manufacturing apparatus 500 further includes an oxidation device 508 to oxidize a metal film.

A gate valve 519 is provided between the etching device 506 and the transfer device 503, and gate valves 516, 517, 518 are provided between the sputter devices (4PVD) 507 and the transfer device 503. Moreover, gate valves 523, 524, 525, 526 are provided between the sputter devices (4PVD) 507 and the transfer device 505. A gate valve 522 is provided between the oxidation device 508 and the transfer device 505.

The transfer device 505 is connected to the LL chambers via the transfer device 503, and thus the inside of the transfer device 505 can be maintained at a high vacuum level. For this reason, in the case where the oxidation process is performed in the oxidation device 508 after the deposition of a metal film in one of the sputter devices 507 connected to the transfer device 505, it is possible to inhibit the impurity adsorption to the surface of the substrate while carrying the substrate inside the transfer device 505. Thus, the oxidation of the metal film impurity adsorption inhibited from occurring on the surface of the metal film enables the formation of a metal oxide film having an excellent uniformity in the order of atomic layer. In addition, in the case of forming a metal stacked film in one of the sputter devices 507 connected to the transfer device 505 and then forming a metal stacked film in another sputter device 507 connected to the transfer device 505, impurity adsorption to the interface of the metal stacked film is so little that the metal stacked films having few lattice defects can be manufactured. Since a perpendicularly magnetized film, in particular, is formed by stacking a large number of metal films, it is important that impurities adsorbed to the interface be few. Use of the apparatus in the present embodiment enables formation of TMR elements having a high resistance change rate by inhibiting deterioration in magnetic properties of the perpendicularly magnetized film. Here, cryopumps may be attached to the mount chambers 504A and 504B.

If the cryopumps are connected to the mount chamber 504A and 504B, the vacuum level in the transfer device 505 can be maintained more stably and preferably. The provision or the cryopumps to the mount chambers 504A and 504B enables, for example, lowering of the water vapor partial pressure in the transfer device 505, and accordingly impurity reduction in interfaces between metal stacked films. This inhibits deterioration in the magnetic properties in the perpendicularly magnetized film and therefore enables the formation of a TMR element having a high resistance change rate.

Moreover, the oxidation device 508 is connected to the transfer device 505 at a position adjacent to the substrate mount chamber 504A, 504B. This leads to reduction in the floor area occupied by the manufacturing apparatus 500 and enables improvement in the vacuum level in the substrate transfer device 505.

This point is explained by use of FIGS. 1 and 2.

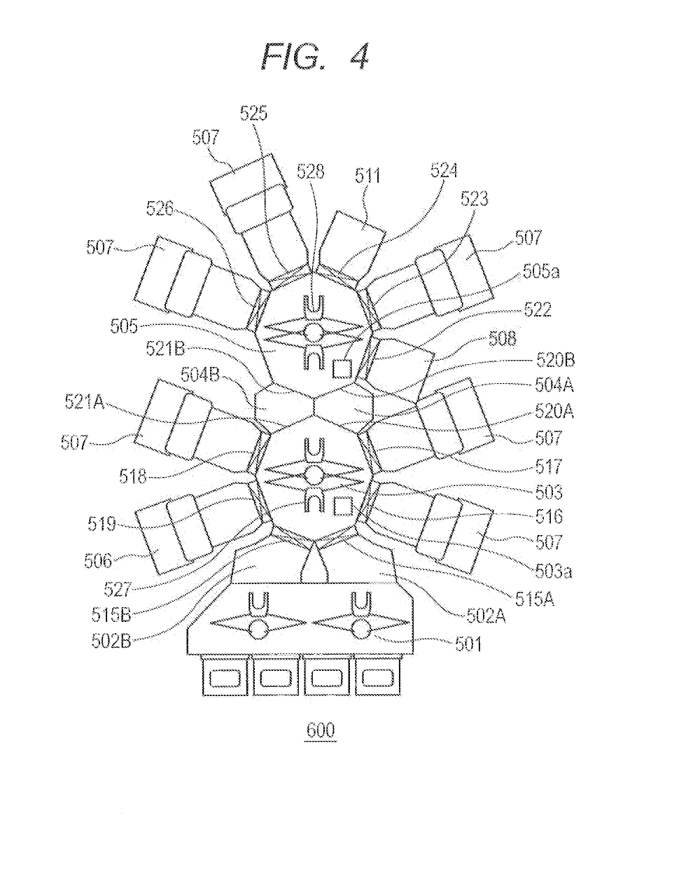

In the manufacturing apparatus in FIG. 1, the oxidation device 409 is connected to the transfer device 405 at a position far from the substrate transfer device 404. In the case where, for example, a STT-TMR including a large number of stacked films is manufactured from the bottom layer to the top layer by a multichamber process of the above apparatus structure, additional sputter devices according to the necessity are further provided to the substrate transfer device 405. The sputter devices used herein are sputter devices each equipped with multiple target cathodes to form multiple stacked films in the multichamber process as described in FIG. 4. Multiple stacked films can be formed by use of a cluster-type manufacturing apparatus in which a necessary number of sputter devices each equipped with multiple target cathodes are connected. The sputter devices are sputter devices each including many sputtering cathodes, and can favorably form multiple stacked films by using many sputtering targets.

However, a sputter device equipped with a large number of sputtering targets is generality large in size. For this reason, if a sputter device is arranged at a position adjacent to the substrate mount chamber 404A or 404B, a large space needs to be reserved between the substrate transfer device 403 and the substrate transfer device 405 in order to prevent the sputter device from coming into contact with the sputter device 407 provided to the substrate transfer device 403. As a result, the floor area of the apparatus is increased. In addition, at least one of the transfer device 403, the mount chambers 404A, 404B and the transfer device 405 needs to be increased in size, and accordingly the vacuum level might be lowered more easily. This problem of size increase is more serious for a sputter device having a larger number of target cathodes, in particular. Moreover, in the present embodiment, each of the sputter devices 407 connected to the transfer device 403 and the transfer device 405 is provided with the evacuation chamber and the evacuation device on the opposite side from the gate valve connected to the transfer device. Due to such structure of the sputter device 407, it is necessary to reserve a much larger space between the substrate transfer device 403 and the substrate transfer device 405.

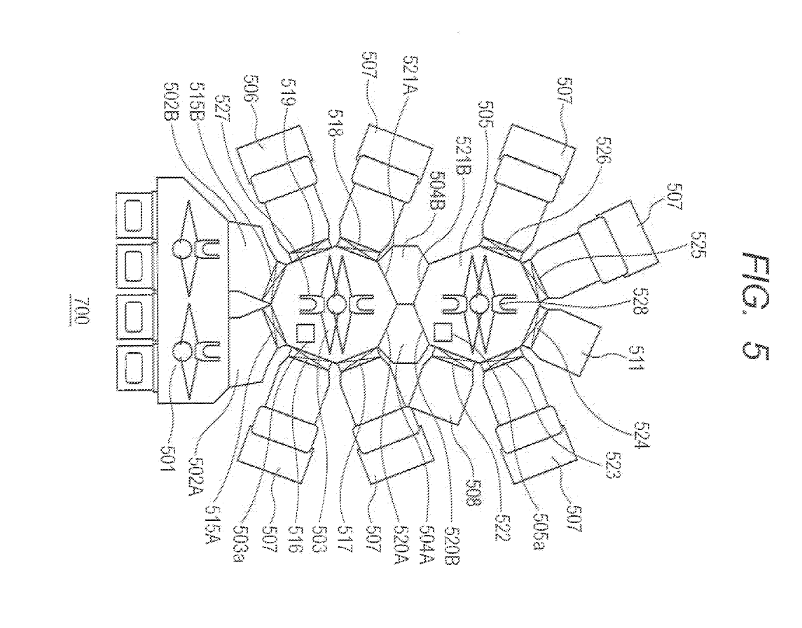

In contrast, if the oxidation device 508, which is smaller than the sputter device 507 including two or more targets, is arranged adjacent to the substrate transfer device 505 as illustrated in FIG. 5, the space between the transfer device 503 and the transfer device 505 necessary to avoid contact with the sputter device 507 connected no the transfer device 503 can be made small. This prevents a site increase in each transfer device, and enables the vacuum level in each transfer device to be maintained favorably.

In the manufacturing apparatus in the present embodiment, the robot arms 527, 528 as transfer means are provided at substantially centers of the respective transfer devices. Each of the robot arms 527, 528 includes a rotation shaft at a substantially center of the transfer device, and transfers a substrate by expanding and contracting an arm provided to the rotation shaft. The robot arm 527, 528 as the transfer means in the present embodiment includes two arms, and these arms may be configured to rotate as one unit, or to be rotatable independently of each other. Connection faces of the transfer device with the process devices and the mount chambers are each perpendicular to an expansion and contraction direction of the arms, and a substrate transfer port of each connection face is configured to be as small as possible. With this structure, the atmosphere inside the transfer device 505 can be maintained at a higher vacuum level. In addition, use of a rotary arm having a rotatable center shaft makes it easier to suppress dust emission and to maintain the high vacuum level in comparison with a slide arm having a centre shaft configured to slide inside the transfer device.

Moreover, in the present embodiment, the mount chambers, the process devices and the like are connected to each transfer device 505, 503 radially with the rotation shaft of the transfer weans centered, and seven and eight chambers and devices in total are connected to the transfer device 505 and transfer device 503, respectively. As in the present embodiment, in the case of a manufacturing apparatus using a transfer device in which connection faces with other devices has a polygonal shape having five or more corners with the rotation shaft centered, contact between a process device provided to the transfer device 503 at a position next to the mount chamber and a process device provided to the transfer device 505 at a position next to the mount chamber tends to be a problem. Even in such a situation, if the oxidation device, which is relatively small in size among process devices, is provided to the transfer device 505 at a position next to the mount chamber 504A or 504B, the sixe increase of the manufacturing apparatus can be suppressed and the vacuum level inside each transfer device can be maintained favorably.

### Third Embodiment

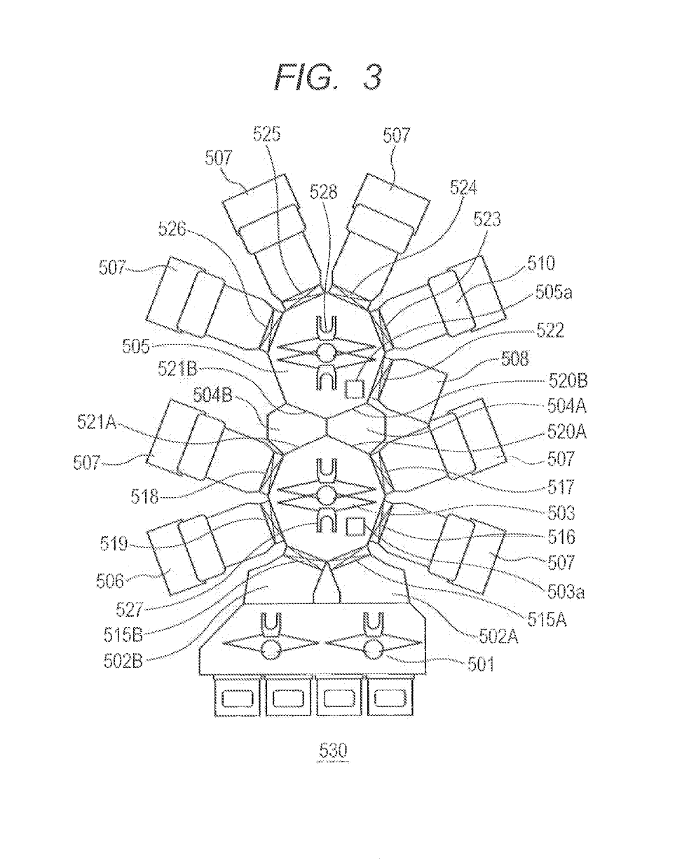

FIG. 3 illustrates a structure of a TMR element manufacturing apparatus 530 according to the present embodiment. This manufacturing apparatus 530 has a structure an which one of the sputter devices 507 provided to the manufacturing apparatus 500 in FIG. 2 is replaced with an anneal device 510. If metal films and metal oxide films are annealed by using this anneal device 510, the crystallinities of a barrier layer, a magnetic free layer and a reference layer, in particular, can be improved and accordingly the resistance change rate can be improved. Such improvement seems to be achieved for the following Reason. Specifically, a metal film deposited by sputtering can be transferred to the anneal device 510, without being kept waiting in a vacuum, by way of the transfer device 505 maintained at a high vacuum level, and then the surface of the metal film can be treated in the anneal device 510. This operation inhibits impurity adsorption to interfaces of the metal stacked film structure, and consequently prevents the occurrence of a crystal defect and property degradation in the metal stacked film structure. In addition, the anneal device 510 has a substrate cooling function and is capable of cooling the substrate immediately after the heating. If a sputter process is performed with a substrate still having a high temperature, a metal film obtained by sputtering may be diffused, which may result In degradation in the flatness at an atomic layer level and induce property degradation in some cases. To avoid this, a substrate needs to be cooled in some cases after the heating process, and the apparatus of the present invention may include a cooling device independently, although not illustrated. As the anneal device 510, a device described in International Patent Application Publication No. WO2010/150590 is preferably used.

### Fourth Embodiment

FIG. 4 illustrates a structure of a TMR element manufacturing apparatus 600 according to the present embodiment. This manufacturing apparatus 600 has a structure in which one of the sputter devices 507 provided in the manufacturing apparatus 500 in FIG. 2 is replaced with an oxidation device 511. For example, in the case of manufacturing a TMR element including an oxide layer in addition to a tunnel barrier layer as described in Non Patent Document 3, the oxidation process needs to be preformed twice.

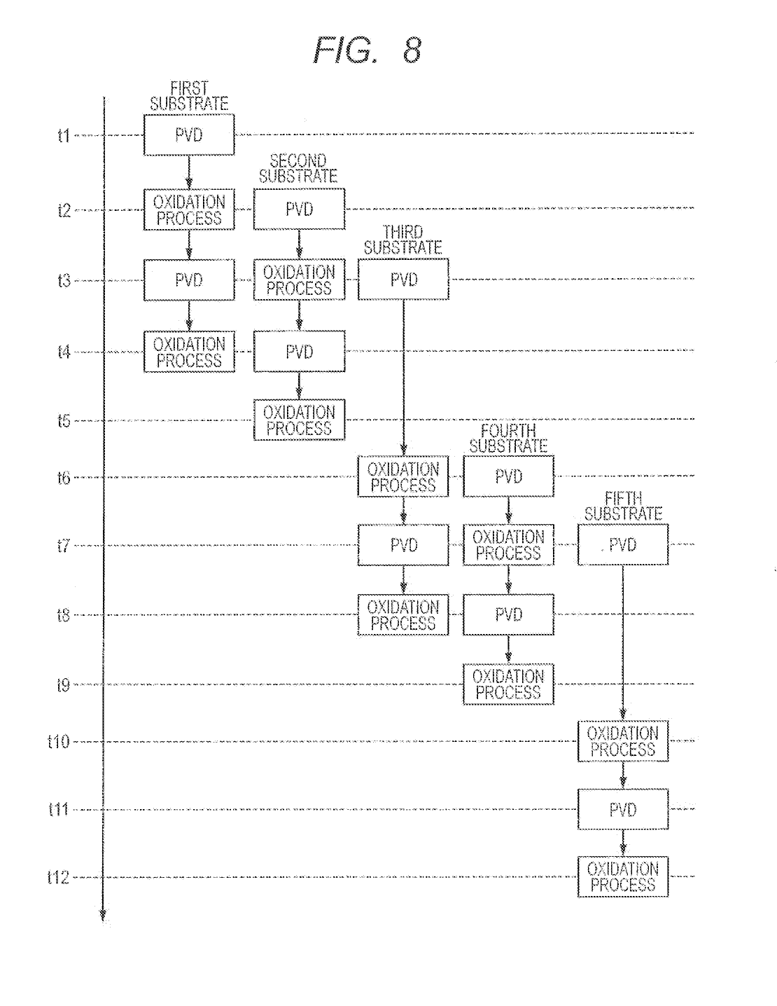

Here, FIG. 8 illustrates an oxidation process for a TMR element in a manufacturing apparatus having only one oxidation device.

FIG. 8 illustrates processes before and after the oxidation process in the manufacturing of TMR elements presented in Non Patent Document 3 by the manufacturing apparatus illustrated in FIG. 2, and a relationship in timing among the processes for substrates. Firstly, after a predetermined film is formed on a substrate, a metal film to be oxidized later is deposited. Then, the metal film is subjected to the oxidation process. Thereafter, a metal film to be oxidized later is deposited again, and the metal film is subjected to the oxidation process. In the case where the oxidation process needs to be preformed twice to manufacture a single TMR film, a single oxidation device 508 needs to be used twice. For the oxidation process for first and second substrates, as illustrated in FIG. 8, a waiting time of each substrate for the oxidation process can be shortened in such a way that each of the first and second substrates is oxidized in turn while the other substrate is subjected so metal film deposition. However, a third substrate needs to wait until the oxidation process for the second substrate is completed. A flow of the processes for the third and following substrates is an iteration of that for the first and second substrates, and the waiting time inevitably occurs in odd-numbered substrates, i.e., the third, fifth and seventh substrates. If the waiting time of a substrate occurs, impurity adsorption and the like on the surface of the substrate may occur during the waiting time. As a result, not only does the throughput decrease, but element properties also degrade. Hence, even though the film deposition by the manufacturing apparatus in FIG. 2 can achieve sufficient reduction in attachment of impurities as compared with a conventional one, and therefore can favorably reduce the occurrence of a crystal defect or property degradation, it is preferable that the manufacturing apparatus achieve further improvement in throughput and element properties than in a structure where the oxidation process is performed twice by the same device.

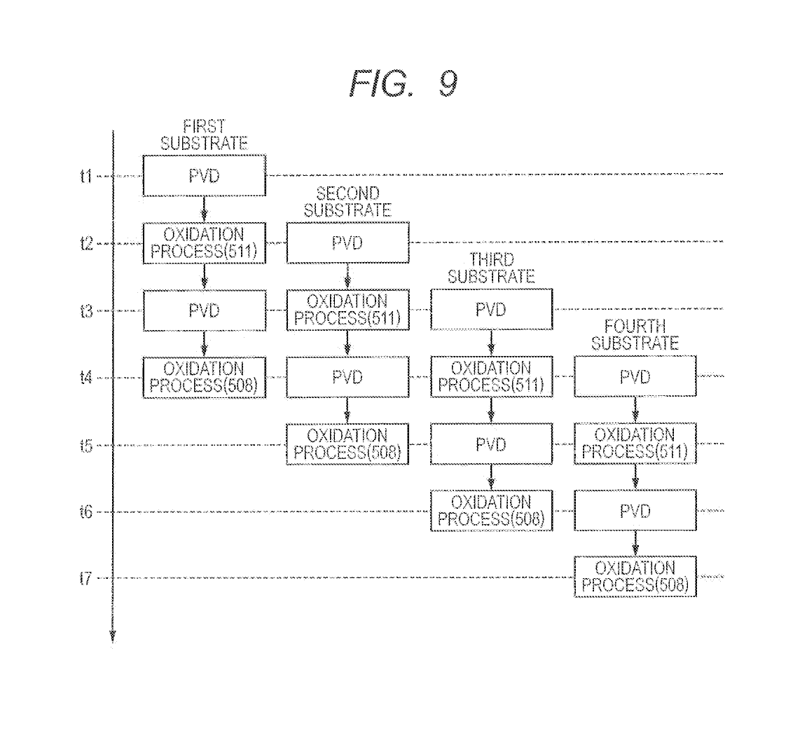

In the manufacturing apparatus 600 according to the present embodiment, two oxidation devices are connected to the transfer device 505. FIG. 9 illustrates processes before and after the oxidation process in the manufacturing of TMR elements presented in Non Patent Document 3 by the apparatus according to the present embodiments and a relationship in timing among one processes for substrates. Firstly, after a predetermined film is formed on a substrate, a metal film to be oxidized later is deposited. Then, the metal film is subjected to the oxidation process in the oxidation device 511. Thereafter, a metal film to be oxidized later is deposited again, and the metal film is subjected to the oxidation process in the oxidation device 508. A second or following substrate is loaded to the oxidation device having already completed the oxidation process on a preceding substrate, and then is subjected to the oxidation process. Thus, it is possible to significantly reduce a waiting time until the completion of the oxidation process on the preceding substrate, although such a waiting time would occur in the apparatus illustrated in FIG. 2. Consequently, the manufacturing apparatus 600 according to the present embodiment is capable of manufacturing TMR elements further excellent in properties while further improving the throughout.

As described above, from the viewpoints of improvement in the productivity and prevention of the occurrence of a crystal defect and property degradation in a metal stacked film structure, it is mere desirable that two or more oxidation devices be connected to the transfer device 505. Such structure is even more desirable, particularly when the oxidation process needs to be preformed two or more times, from the viewpoints of improvement in the productivity and prevention of the occurrence of a crystal defect and property degradation in a metal stacked film structure. From the aspect of simplification of a control program, it is preferable that the number of oxidation devices be set to be equal to the number of times of the oxidation process.

Incidentally, also in the present embodiment, one of the sputter devices 507 may be replaced with an anneal device 510 as described in the third embodiment.

### Fifth Embodiment

In the apparatus according to the foregoing embodiment, the mount chambers 504A and 504B are provided between the transfer device 505 and the transfer device 503. Thus, the transfer device 505 is maintained at a higher vacuum level than the transfer device 503. However, in the structure where the transfer device 505 is provided with an oxidation device, the vacuum level of the transfer device 505 tends to be lowered due to an oxygen gas and the like introduced in the oxidation device. A method conceivable to address this problem is to evacuate the oxidation device up to a predetermined vacuum level after the oxidation device performs a predetermined oxidation process on a substrate. This method, however, does not allow the next oxidation process to be performed until the evacuation of the oxidation device is completed, which eventually leads to decrease in the throughput.

The present embodiment enables the oxidation process on the next substrate to be performed before completion of full evacuation of the oxidation device, while inhibiting degradation in element properties from occurring on another substrate. The present embodiment is herein explained by using FIG. 5.

Gate valves 515A, 515B, 516, 517, 518, 519, 520A, 520B, 521A, 521B, 522, 523, 524, 525 and 526 which are each operable and closable for isolating adjacent spaces from each other are provided between substrate process devices, transfer devices and mount chambers. In the present embodiment, a control device (for example, the control device 900 illustrated in FIG. 13) provided to a manufacturing apparatus 700 controls the above gate valves, a robot arm 527 of a transfer device 503 and a robot arm 528 of a transfer device 505.

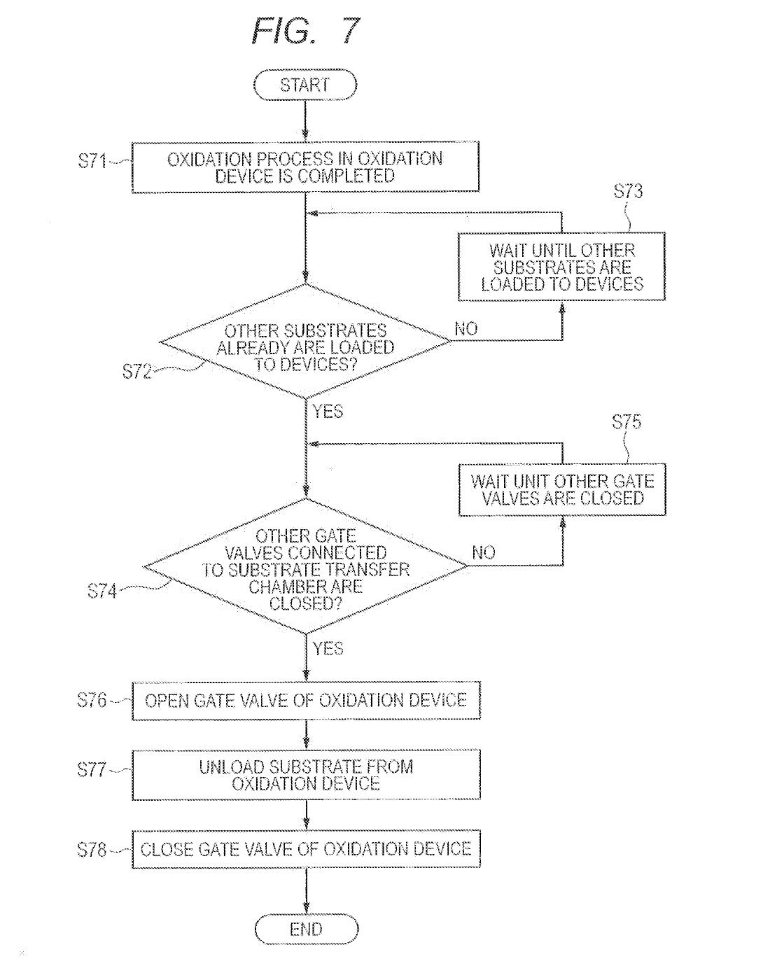

The control device (for example, the control device 900 illustrated in FIG. 13) controls the gate valves and the robot ante 527 and 528 in accordance with a flow illustrated in FIG. 7.

Hereinafter, description is provided for the flow illustrated in FIG. 7.

To begin with, in step S71, the control device performs the oxidation process by using at least one of an oxidation device 508 and an oxidation device 511. After completion of the oxidation process on the substrate in the at least one of the oxidation device 508 and the oxidation device 511, the control device judges in step S72 whether or not another substrate to be treated is already loaded from the transfer device 505 to any of the other oxidation device, sputter devices, and mount chambers 504A and 504B connected to the transfer device 505. If there is a substrate yet to be loaded, the control device waits while leaving the substrate mounted inside the oxidation device 508, 511 in step S73, until the control device confirms that the loading of the substrate in the transfer device 505 to any of the process devices or the mount chambers is completed.

Nested that, another substrate to be oxidized next does not have to be completely loaded to the oxidation device, but is desirable to be loaded to the oxidation device in order to obtain stable element properties.

After all the substrates are loaded to the sputter devices, the other oxidation device or the substrate mount chamber 504A or 504B, the control device judges in step S74 whether or not the gate valves provided to the respective devices and chambers are closed. If there is a gate valve yet to be closed, the control device leaves the substrate waiting in the oxidation device in step S75. In step S76, after all the gate valves are closed, the control device opens the gate valve between the substrate transfer device 505 and the oxidation device in which the substrate after completion of the oxidation process is mounted, and the transfer device unloads the substrate by using the robot arm 528 in stop S77. Thereafter, in step S78, the control device closes the gate valve of the oxidation device. In order to keep a constant atmosphere inside each of the oxidation device, it is desirable not to simultaneously open the gate valves provided between the transfer device 505 and the two oxidation devices. More specifically, the control device controls the gate valves such that while one of the gate valves between the transfer device 505 and the oxidation devices or the gate valves between the transfer device 505 and the mount chambers 504A, 504B is opened, the other gate valve will not be opened.

In this way, the opening timing of the gate valve of the oxidation device after the substrate process is set not to coincide with the opening timing of the other gate valves, and thereby the oxygen gas can be prevented from flowing into any other process device.

Note that the effect described in the present embodiment is larger in the case where there are two or more oxidation devices as described in the third or fourth embodiment, than in the case where there is only one oxidation device as in the first or second embodiment.

### Sixth Embodiment

As described above, especially in the fourth or fifth embodiment, since there are two or more oxidation devices provided to the transfer device 505, the vacuum level of the transfer device 505 particularly tends to be lowered due to the oxygen gas or the like introduced to the oxidation device. In addition, since the oxidation device is connected to the transfer device 505, even the first or second embodiment may also have the problem that the vacuum level of the transfer device 505 tends to be lowered due to the oxygen gas or the like introduced to the oxidation device. The present embodiment is characterized in that, to address the above problem, a component member such as a shield made of a substance having an oxygen gettering effect is provided in a process device connected to the transfer device 505.

Here, it is particularly preferable to use a substance having a lager adsorption energy to the oxygen gas than MgO forming a tunnel barrier layer, which will largely affect the element properties of a TMR element. The adsorption energy of MgO to the oxygen gas is about 150 kcal/mol. Substances having a larger adsorption energy than that include Ti, Ta, Mg, Cr, Zr and the like. A component member made of Ti is particularly preferable from the viewpoints of workability, effective oxygen adsorption and the like.

In addition, for a magnetic film in which magnetic properties may degrade due to oxidation, use of a substance having an oxygen gettering effect for a device component member can be expected to further improve the element properties. As such substance, Ti and Ta can be cited.

Instead of providing a component member having a gettering effect inside a sputter device, a target containing a substance having an oxygen gettering effect may be provided inside the sputter device. Then, the substance having the oxygen gettering effect (“getter film”) is sputtered and attached to the inner wall of the device before the firm deposition process, and thereby an oxygen amount inside the sputter device is decreased.

Note that, although not all the sputter devices need to perform sputter to form the getter film before film deposition on a substrate, it is desirable to perform such sputter particularly at least before deposition of a MgO film and a magnetic film which will largely affect time TMR element properties. Ti and Ta are preferable as substances having oxygen gettering effects. Alternatively, a sputter device may be provided with a component member for the getter film in advance and then may perform sputter for the getter film.

### Seventh Embodiment

The foregoing embodiment may be formed by attaching an RF power source to any of the sputter devices 507 connected to the transfer device 505, and thereby be configured to additionally use a direct reactive sputter or an RF sputter using an oxide target or the like. Two or more mechanisms for the RF sputter can be installed depending on a desired TMR element. Specifically, two or more RF cathodes can be provided to one sputter device 507, or one RF cathode can be provided to each of two sputter devices 507 in the case where two oxide layers are needed. Alternatively, the foregoing exudation process and the RF sputter may be combined.

When two or more RF cathodes are provided to one chamber, the throughput can be improved because the film deposition speed increases in proportion to the number of RF cathodes.

Moreover, as illustrated in FIG. 3, an insulator film deposited by RF sputter may be annealed by using the anneal device 510. Since the insulator film deposited by RF sputter is quickly transferred to the anneal device 510 by use of the transfer device 505 maintained at a high vacuum level and then is annealed on its surface by the anneal device 510, the impurity adsorption to the interface can be inhibited, and thereby the occurrence of a crystal defect and property degradation in a metal stacked film structure can be inhibited.

### Eight Embodiment

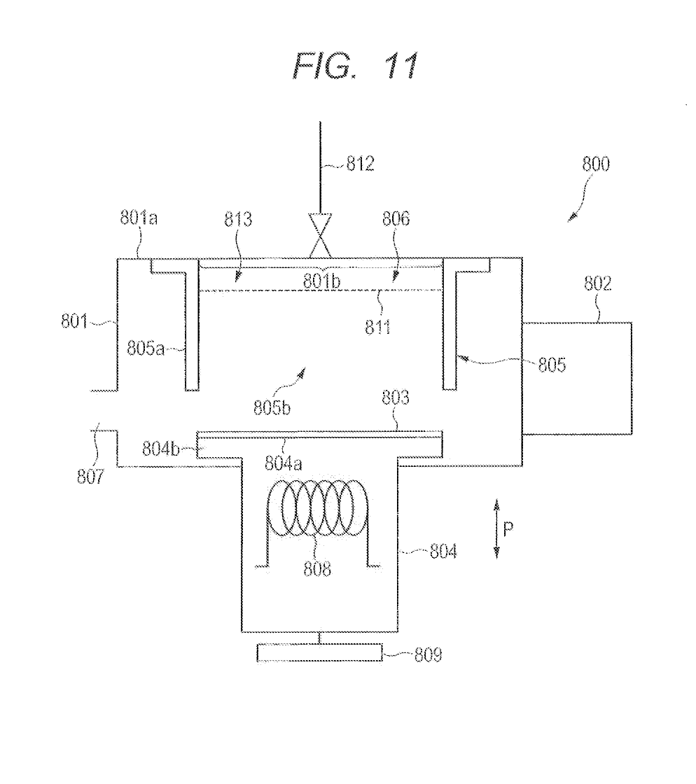

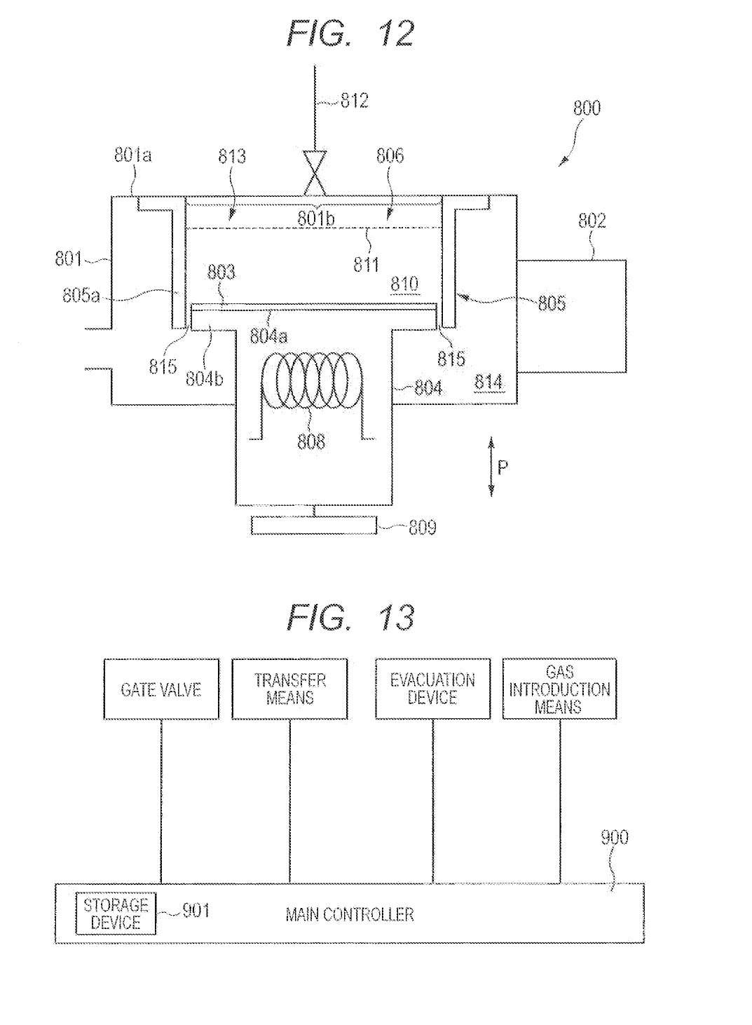

As the oxidation devices 508 and 511 connected to the transfer device 505, the present embodiment uses an oxidation device more suitable to maintain the transfer device 505 at a high vacuum level. With reference to FIGS. 11 and 12, an oxidation device 800 according to the present embodiment is explained.

The oxidation device 800 includes a process chamber 801, a vacuum pump 802 as an air evacuator for evacuating the process chamber, a substrate holder 804 provided inside the process chamber 801 and configured to hold a substrate 803, a tubular member 805 provided inside the process chamber 801, a gas introduction unit 806 as oxygen gas introduction means for introducing an oxygen gas into the process chamber 801, and a substrate transfer port 807. The substrate transfer port 807 is provided with a slit valve not illustrated.

The substrate holder 804 includes a substrate holding surface 804a for holding the substrate 803 and a mounting portion 004b on which the substrate holding surface 804a is formed. The substrate 803 is mounted on the substrate holding surface 804a. In addition, a heater 800 as a heating device is provided inside the substrate holder 804. Moreover, a substrate holder driving unit 809 as position changing means for changing a relative position between the substrate holder 804 and the tubular member 805 is connected to the substrate holder 804. The substrate holder driving unit 809 moves the substrate holder 804 in arrow directions P (a direction in which the substrate holder 804 comes closer to an oxidation process space 810 and a direction in which the substrate holder 804 goes away from the oxidation process space 810). In the present embodiment, at a time of transferring a substrate, the substrate holder 804 is moved to a position illustrated in FIG. 11 under the control of the substrate holder driving unit 809. In loading a substrate, in the above state, the substrate 803 is loaded to the process chamber 801 via the substrate transfer port 807, and the substrate 803 is mounted on the substrate holding surface 804a. In unloading the substrate, the substrate 803 held on the substrate holding surface 804a is unloaded from the process chamber 801 via the substrate transfer port 807. On the other hand, at a time of the oxidation process, the substrate holder 804 is moved to a position illustrated in FIG. 12 under the control of the substrate holder driving unit 809. In this state, the oxygen gas is introduced exclusively to the oxidation process space 810 (the oxygen gas is introduced to a limited space inside the process chamber 801) by the gas introduction unit 806, and thereby the oxidation process is performed.

The gas introduction unit 806 includes: a shower plate 811 provided away from a wall 801a of the process chamber 801 opposed to the substrate holder 804, the shower plate 811 having a large number of holes; an oxygen introduction passage 812 provided on top of the wall 801a and including a gas inlet for introducing the oxygen gas into the process chamber 801; and a gas diffusion space 813 being a space between the shower plate 811 and the wall 801a and used to diffuse the oxygen gas introduced from the oxygen introduction passage 812. In the present embodiment, the oxygen introduction passage 812 is provided so as to introduce the oxygen gas to the diffusion space 813, and the oxygen gas introduced from the oxygen introduction passage 812 and diffused in the diffusion space 813 is supplied evenly to the surface of the substrate via the shower plate 811. Incidentally, two or more oxygen introduction passages 812 may be provided.

The tubular member 805 is a member including an extending portion 805a attached to the wall 801a of the process chamber 801 so as to entirely surround the shower plate 811 and a region 801b in the wall 801a, the region 801b at least including a portion to which the oxygen introduction passage 815 is connected. The extending portion 805a extends from the wall 801a to a side opposed to the wall 801a (here, a substrate holder 804 side). In the present embodiment, the tubular member 805 is a tube-form member having a circular cross section taken perpendicularly to the extending direction. However, the tubular member 805 may have the cross section in another shape such as a polygon. In addition, the tubular member 805 is made of Al, for example. Al is preferable because Al is easy to process to form the tubular member 805. Instead of Al, Ti or SUS may also be used, for example. The tubular member 805 may be formed such that the tubular member 805 can be detachably attached to the wall 801a. A space surrounded by the extending portion 805a, i.e., a hollow portion of the tubular member 805 is provided with the shower plate 811. The diffusion space 813 is formed by a portion of the tubular member 805 between the shower plate 811 and the wall 801a, at least part of the region 801b in the wall 801a, and the shower plate 811.

The shower plate 811 and the tubular member 805 are provided, so that the oxygen gas can be supplied more evenly to the surface of the substrate 803, and unevenness in an oxidation distribution of MgO generated by oxidation on the surface of the substrate 803 can be reduced. Thus, a RA distribution can be improved.

Since the oxygen gas is introduced from the holes of the shower plate 811 to the oxidation process space 810, the shower plate 811 can be called a region provided with portions for introducing the oxygen gas exclusively into the oxidation process space (the region is also referred to as “an oxygen gas introduction region”).

Incidentally, in the case where no shower plate 811 is provided as one example, the oxygen gas is introduced exclusively into the oxidation process space 810 from the oxygen introduction passage 812, and the region 801b serves as the oxygen gas introduction region.

In the present embodiment, the oxidation process space 810 can be said to be formed by the oxygen gas introduction region, the tubular member 805, and the substrate holder 804 (substrate holding surface 804a).

Moreover, as illustrated in FIG. 12, the tubular member 805 is provided such that a clearance 815 can be formed between the extending portion 805a and at least part of the substrate holder 804 (the mounting portion 804b), when the substrate holder 804 is inserted in an opening portion 805b of the tubular member 805 the tubular member 805. In other words, the tubular member 805 is configured to, when forming the oxidation process space 810, surround the substrate holding surface 804a with the clearance 815 provided between the mounting portion 804b having the substrate holding surface 804a formed thereon and the extending portion 805a. Thus, the oxygen gas introduced from the gas introduction unit 800 into the oxidation process space 810 is discharged from the oxidation process space 810 to an external space 814 outside the oxidation process space 810 via the clearance 815. The oxygen gas discharged from the oxidation process space 810 to the external space 814 via the clearance 815 is evacuated from the process chamber 801 by the vacuum pump 802.

The substrate holder driving unit 809 moves the substrate holder 804 in one of the arrow directions P so that the substrate holding surface 804a can be accommodated inside the tubular member 805, and stops the movement of the substrate holder 804 at a predetermined position where the substrate holding surface 804a mounting portion 804b) is inserted in the opening portion 805b. In this way, the oxidation process space 810 communicating with the external space 814 only via the clearance 815 is formed as illustrated in FIG. 12. In this state, the oxidation process space 810 is formed by the shower plate 811, the extending portion 805a and the substrate holder 804 (substrate holding surface 804a). Thus, in the present embodiment, an enclosure portion of the present invention is the shower plate 811 and the extending portion 805a. Hence, the tubular member 805 is an enclosure member for defining the oxidation process space 810 in cooperation with the shower plate 811 and the substrate holder 804 (substrate holding surface 804a) during the oxidation process such that the oxygen gas introduced by the gas introduction unit 806 can be introduced exclusively into the oxidation process space 810 in the process chamber 801.

Incidentally, in the case where no shower plate 811 is provided as one example described above, the oxidation process space 810 is formed by the region 801b, the extending portion 805a and the substrate holder 804. In this case, the enclosure portion of the present invention is the region 801b being the part of the inner wall of the process chamber 801 and the extending portion 805a.

In the present embodiment, it is important that the oxidation process space 810 can be formed in such a way that the relative position between the substrate holder 804 and the tubular member 805 is changed by the substrate holder driving unit 809. To this end, the substrate holder driving unit 809 is configured to move the substrate holder 804 in the arrow directions P which are one-axial directions. However, the structure is not limited to this. Any structure can be employed as long as the structure can locate the substrate holding surface 804a inside the tubular member 805 to form the oxidation process space 810 at least on the occasion of the oxidation process, and can locate the substrate holding surface 804a outside the tubular member 805 in the other occasions (for example, on the occasion of substrate transfer). In one possible structure, for example, the substrate holder 804 is fixed, and the tubular member 805 and the gas introduction unit 806 are joined as a unit. In this case, the unit, i.e., the tubular member 805 and the gas introduction unit 806 as the unit are brought closer to the substrate holder 804 to form the oxidation process space 810. Instead, in another possible structure, the substrate holder 804 is configured to be slidable also in right and left directions of the tubular member 805, and is moved to a position where the substrate holder 804 is not opposed to the opening portion 805b, when not forming the oxidation process space 810.

In the present embodiment, the substrate holding surface 804a has a circular shape. The cross section of the tubular member 805 taken perpendicularly to the extending direction of the extending portion 805a has a shape similar to an outside shape of the substrate holding surface 804a (mounting portion 804b). In other words, the cross section has a circular shape. In addition, when the oxidation process space 810 is formed, the shower plate 811 and the substrate holding surface 804a are opposed to each other, and the clearance 815 is also opposed to the shower plate 811. In this state, it is preferable that the size of the clearance 815 be constant in a circumferential direction of the substrate holding surface 804a. With this structure, the air discharge conductance in the entire clearance 815 formed in the circumferential direction of the substrate holding surface 804a can be set to a constant value. In other words, the air can be discharged evenly from the entire circumference of the clearance 815 functioning as an air outlet from the oxidation process space 810. This makes it possible to apply a uniform oxygen pressure to the surface of the substrate 803 mounted on the substrate holder 804 under the condition where the oxidation process space 810 is formed, and thereby to improve the RA distribution.

Moreover, in the present embodiment, the substrate holder driving unit 809 is configured to move the substrate holder 804 inside the tubular member 805 along the extending direction of the extending portion 805a. To put it differently, the substrate holder driving unit 809 is capable of moving the substrate holder 804 inside the tubular member 805 in a direction toward the shower plate 811 as the oxygen gas introduction region and in a direction away from the shower plate 811.

Additionally, in the present embodiment, the mounting portion 804b hawing the substrate holding surface 804a and being a region of the substrate holder 804 forming the clearance 815 is formed to have the same size along the extending direction of the extending portion 805a. To be more specific, the substrate holder 804 and the tubular member 805 are configured such that: the diameter of the tubular member 805 is constant in the extending direction of the extending portion 805a; the diameter of the mounting portion 804b is also constant in the extending direction; and therefore the air discharge conductance in the clearance 815 for the gas from the oxidation process space 810 can be unchanged even if the mounting portion 804b being the closest portion of the substrate holder 804 to the extending portion 805a is moved inside the tubular member 805 in the directions toward and away from the shower plate 811. Thus, even when the substrate holder 804 is moved inside the tubular member 805, the oxygen gas can be discharged from the oxidation process space 810 in the same way, and accordingly the complication of the process control can be reduced.

Moreover, in the present embodiment, it is preferable that the inner wall portion of the tubular member 805 be smoothed through an electro polishing process or a chemical polishing process. In the present embodiment, the inner wall of the tubular member 805 is flattened. When the surface roughness of the inner wall of the tubular member 805 is reduced as described above, the adsorption of the oxygen gas to the inner wall of the tubular member 805 and the release of the oxygen gas adsorbed to the inner wall can be reduced. In addition, it is also preferable that the surface of the inner wall of the tubular member 805 be coated with a film resistant to adsorption of an oxygen gas (for example, a passive film such as an oxide film). The formation of a passive film on the surface of the inner wall of the tubular member 805 results in reduction in the adsorption el oxygen to the surface of the inner wall. For example, the tubular member 805 is made of Al, and the inner side of the tubular member 805 is processed by the chemical polishing. In this case, the surface of the inner wall of the tubular member 805 is flattened and an oxide film can be formed thereon. In cooperation with the effect produced by the flartening, the oxide film thus formed can reduce the adsorption of oxygen to the tubular member 805 can be reduced.

Moreover, according to the present embodiment, a smaller space (the oxidation process space 810) than the space defined by the inner wall of the process chamber 801 is formed inside the process chamber 801, one part of the oxidation process space 810 is defined by the substrate holding surface 804a, and the substrate 803 held by the substrate holding surface 804a is exposed to the oxidation process space 810. Then, the oxygen gas is supplied exclusively to the oxidation process space 810 to perform the oxidation process on the substrate 803. In this process, the air is discharged from the oxidation process space 810 via the clearance 815 formed between the tubular member 805 and the substrate holder 804. In this way, in the present embodiment, for the oxidation process, the oxygen gens is supplied only to a limited space (the oxidation process space 810) of the process chamber 801, and then the oxidation process is performed. Thus, it is possible to reduce a time required until the pressure in the space to be filled with the oxygen gas for the oxidation process reaches a predetermined level, surd also to reduce a time required to evacuate the air. With this structure, the oxygen gas can be inhibited from flowing out into the transfer device 505 at a high vacuum level on the occasion of substrate transfer between the oxidation device 507 and the transfer device 505. Thus, a thin film with higher quality can be deposited.

Further, the smaller space (the oxidation process space 810) than the space defined by the inner wall of the process chamber 801 is formed inside the process chamber 801, and the oxidation process is performed inside the smaller space. Thus, the surface area of the members defining the space for performing the oxidation process can be seduced significantly as compared with a conventional case. Accordingly, the amount of oxygen adsorbed to the tubular member 805 forming the oxidation process space 810 for performing the oxidation process can be reduced, said also the amount of oxygen released from the inner wall of the tubular member 805 after evacuation can be reduced significantly. These points are also advantageous to maintain the high vacuum level of the transfer chamber 505.

Furthermore, since the oxidation process space 810 is defined inside the process chamber 801 by using the tubular member 805 which is a member separate from the inner wall of the process chamber 801, the shape of the oxidation process space 810 can be set freely. Thus, the cross section of the oxidation process spaces 810 taken parallel to the surface of the substrate 803 (substrate holding surface 804a) can have a shape similar to the outside shape of the substrate 803 (substrate holding surface 804a). In the conventional case, if a process chamber is cylindrical and an outside shape of a substrate (substrate holding surface) is rectangular, a space for performing an oxidation process has a circular cross section taken parallel to the surfaces of the substrate (substrate holding surface) and the cross sectional shape is different from the outside shape of the substrate (substrate holding surfaces). In contrast, in the present embodiment, if the process chamber 801 is cylindrical and the outside shape of the substrate 803 (substrate holding surface 804a) is rectangular, for example, the tubular member 805 having a rectangular cross section can be attached to the inside of the process chamber 801, and thereby the cross sectional shape of the oxidation process space 810 can be made similar to the outside shape of the substrate 803 (substrate holding surface 804a). When the cross sectional shape of the oxidation process space 810 and the outside shape of the substrate 803 (substrate holding surface 804a) are similar shapes as described above, the width of the clearance 815 in the circumferential direction of the substrate 803 (substrate holding surface 804a) can be made constant, and accordingly the air discharge conductance thereof can be also made constant. Thus, the oxidation distribution on the surface of the substrate 803 can be reduced.

By use of the oxidation device according to the present embodiment as described above, an introduction amount of oxygen needed for the oxidation process on a substrate can be reduced, and the oxygen gas after a predetermined oxidation process can be evacuated quickly. Hence, a flow amount of oxygen gas flowing out from the oxidation devices 508 and 511 to the transfer device 505 can be reduced, and the transfer device 505 can be maintained at a higher vacuum level.

### Ninth Embodiment

In a substrate process system according to the present invention, the oxidation device 508 is connected to the transfer device 505 at a higher vacuum level in order to form a tunnel barrier layer with high quality. In the case where the oxidation device 503 is connected to the transfer device 505 at a high vacuum level, however, the oxygen pressure inside the transfer device 505 may possibly rise due to the oxygen gas flowing out from the oxidation device 508. Such a problem can occur particularly when the oxidation device 508 cannot be evacuated sufficiently after the oxidation process in the oxidation device 508 from the viewpoint of throughput improvement.

When the oxygen pressure inside the transfer device 505 rises, the interface of a thin film may adsorb oxygen or may be unintentionally oxidized during the transfer of a substrate to another process device after the formation of the thin film in the sputter device 507. Such adsorption or oxidation may degrade device properties. Among thin films constituting a device, the process device connected to the transfer device 505 is used to process a thin film requiring a cleaner atmosphere, in particular. For this reason, it is desirable first the exposure of an interface of such a thin film to oxygen be reduced as much as possible.

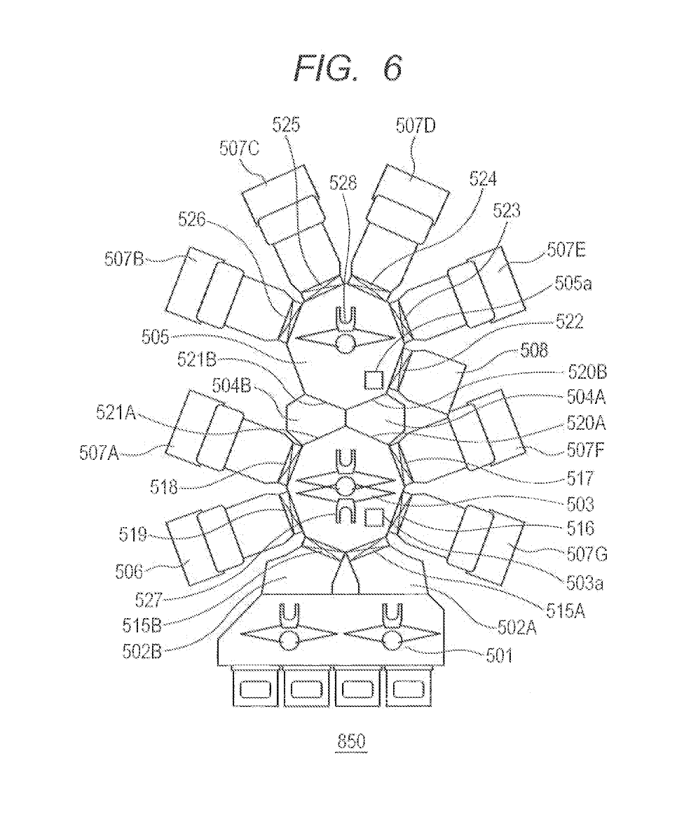

In the present embodiment, in transferring a substrate between process devices via the transfer device 505, a residence time of the substrate in the transfer device 505 is shortened as compared with a residence time in the transfer device 503, and thereby a time of line of exposure of a thin film interface to oxygen (an amount of exposure to the oxygen gas) is shortened. FIG. 6 illustrates a substrate process system according to the present embodiment. In an apparatus according to the present embodiment, two robot arms 527 are provided to the transfer device 503, whereas a single robot arm 528 is provided to the transfer device 505. In a conventional apparatus, two or more robot arms are provided to a transfer device to increase the number of substrates processable per unit time, and the number of substrates allowed to stay in the substrate process system is increased. In such a substrate process system, however, residence times of substrates in the transfer device 503 and the transfer device 505 tend to be longer than in the case where a single robot arm is provided. Here, a transfer device provided with two robot and is described as one example. After a substrate process is completed in a first process device, a first arm of the two robot arms unloads a second substrate from the first process device. Then, a first substrate held by the second arm of the two robot arms is loaded to the first process device. Next, the second arm is set standby in front of a second process device where to load the second substrate next. After a process on a third substrate in the second process device is completed, the third substrate is unloaded by the second arm. Then, the second substrate held by the first arm is loaded to the second process device.

In this transfer method, each substrate after completion of the process in a process device needs to wait in front of a next process device inside the transfer device until the process on a substrate performed in the next process device is completed. During this waiting time, the surface of a thin film formed on the topmost surface on the substrate is exposed to the oxygen gas inside the transfer device.

In the present embodiment, two robot arms 527 are provided to the transfer device 503, whereas a single robot arm 528 is provided to the transfer device 505. In the case where the single robot arm is provided, a substrate after the completion of the process in each process device is loaded to the next process device immediately. Instead, if the process en a preceding substrate is ongoing in the next process device, the preceding substrate is first loaded to the second next process device after completion of the process on the preceding substrate, and then the substrate is transferred to the next process device. Thus, by eliminating a time for which the substrate waits inside the transfer device, a time for which a substrate stays inside the transfer device can be reduced as much as possible.

In addition, since the transfer device 503 is provided with two robot arms, it is possible to shorten a residence time of each substrate in the transfer device 505 while suppressing a reduction in throughput by adjusting substrate process times of the process devices connected to the transfer device 503 and substrate process times of the process devices connected to transfer device 505.

### Tenth Embodiment

In the foregoing ninth embodiment, two or more robot arms are provided to the transfer device 503 and only one robot arm is provided to the transfer device 505, so that the residence time of a substrate in the transfer device 505 is reduced while a reduction in throughput is suppressed.

In contrast, the present embodiment is intended to reduce a residence time of a substrate in the transfer device 505 while two or more robot arms are provided to the transfer device 505.

In description of the present embodiment, as for the transfer methods described in the ninth embodiment, the transfer method using two robot arms is called a first movie and the transfer method using a single robot is called a second mode. The present embodiment is characterized in that the first mode and the second mode are switched while a substrate is being transferred by the robot arms provided to the transfer device 505.

The process devices connected to the transfer device 505 performs processes on a substrate, and there are some processes, after completion of which the substrate is unloaded to the transfer device 505 while having the topmost surface relatively little sensitive to influence by oxygen. Even if a substrate in such a state little sensitive to the influence by oxygen is kept waiting in the transfer device 505, the resultant elements may be only little affected. The present embodiment is characterized in that a substrate carried in the transfer device 505 is transferred in the first mode when the substrate is in the state relatively little sensitive to the influence by oxygen, and then the transfer method is transitioned to the second mode once a film highly sensitive to the influence by oxygen is formed on the topmost surface of the substrate.

Hereinafter, detailed description is provided by using an example in which multiple stacked films presented in Non Patent Document 2 are manufactured by using a substrate process system 850 according to the present embodiment.

Firstly, a substrate loaded to the substrate process system 850 is treated by an etching device 506 connected to a transfer device 503 to remove impurities and the like attached to the surface. Next, the substrate is

transferred to a transfer device 505 and is loaded to a sputter device 507B. The sputter device 507B forms seed layers made of RuCoFe and Ta, and flattens the surface of the substrate. Then, the substrate is loaded to a sputter device 507C, which forms a CoFeB layer as a magnetic free layer and a Mg layer to be turned into a tunnel barrier layer by the following oxidation process. Here, the substrate is transferred in the first mode in the transfer from the mount chamber 504A or 504B to the sputter device 507B and the transfer from the sputter device 507B to the sputter device 507C, because the surface of the substrate after the etching and the surface of the seed layer are less sensitive to the influences by oxygen.

After the Mg layer is formed on the substrate, the substrate is loaded into an oxidation device 508 and is oxidized to form the tunnel barrier layer. Thereafter, the substrate is loaded to a sputter device 507D, which forms a Fe layer and a CoFeB layer as magnetic pinned layers. Subsequently, the substrate is transferred to a sputter device 507E, which forms a Ta layer, a Co layer and a Pt layer. Then, the substrate is transferred to the transfer device 503 via the mount chamber 504A or 540B, and the films following the Pt layer are formed by sputter devices 507A, 507F, 507G. In these manufacturing steps, if the surface of the Mg layer to be oxidized to the funnel barrier layer, the MgO layer as the tunnel barrier layer, or the CoFeB layer as the magnetic pinned layer is exposed to a large amount of oxygen gas, the quality of the tunnel barrier layer will degrade or the magnetic properties of the magnetic pinned layer will degrade. For this reason, in the transfer from the sputter device 507C to the oxidation device 508, the transfer from the oxidation device 508 to the sputter device 507D, and the transfer from the sputter device 507D to the sputter device 507E, it is desirable to transfer the substrate in the second mode in which the residence time in the transfer device 505 is short. Here, in the transfer in the second mode, transfer from a certain process device to the next process device requires that another substrate should not stay in the next process device. For this reason, the second next process device needs to be emptied in order to empty the next process device. Accordingly, once the transfer method is switched to the second mode, the substrate is transferred in the second mode until it is transferred to the mount chamber 504A or 504B.

The foregoing example is described for the case where the surfaces of the Mg layer, the MgO layer and the CoFeB layer are exposed to the atmosphere inside the transfer device 505. However, for a TMR element as described in Non Patent Document 2, what are very important are the film quality of the tunnel barrier layer and the magnetic properties of the magnetic free layer and the magnetic pinned layer adjacent to the tunnel barrier layer. Hence, the timing for switching the first mode to the second mode is determined so as to shorten a time period in which these films are exposed to the atmosphere inside the transfer device 505.

By use of FIG. 13, description is provided for a control device to operate a manufacturing apparatus according to an embodiment of the present invention. The control device includes a main controller 900. A storage device 901 included in the main controller 900 stores a control program for executing various substrate treatment processes according to the present invention. For example, the control program is implemented as a mask ROM. Instead, the control program can be installed via an external recording medium or network to the storage device 901 configured of a hard disk drive (HDD) or the like. The main controller 900 controls the opening and closing operations of the gate valves provided between the process devices, the transfer devices, the mount chambers and the LL chambers, and controls the transfer means provided to the transfer devices. Moreover, the main controller 900 is also capable of controlling the evacuation device, the gas introduction means and others provided to each device.

1. A tunnel magneto-resistance element manufacturing apparatus comprising:
a load lock device configured to load and unload a substrate from and to an outside;
a first substrate transfer device that is connected to the load lock device, at least one substrate process device being connected to the first substrate transfer device;
a first evacuation device provided in the first substrate transfer device; and
a second substrate transfer device that is connected to the first substrate transfer device, a plurality of substrate process devices being connected to the second substrate transfer device; and
a second evacuation device provided in the second substrate transfer device, wherein
at least one of the plurality of substrate process devices connected to the second substrate transfer device is an oxidation device.

2. The manufacturing apparatus according to claim 1, wherein a substrate mount chamber is provided between the first substrate transfer device and the second substrate transfer device.

3. The manufacturing apparatus according to claim 1, wherein a plurality of oxidation devices are connected to the second substrate transfer device.

4. The manufacturing apparatus according to claim 2, wherein a cryopump is provided in the substrate mount chamber.

5. The manufacturing apparatus according to claim 3, wherein
at least one of the plurality of oxidation devices is connected to the second substrate transfer device at a position adjacent to the substrate mount chamber.

6. The manufacturing apparatus according to claim 5, wherein
at least one of the at least one substrate process device connected to the first substrate transfer device is a sputter device,
the sputter device includes an evacuation chamber on an opposite side from a side connected to the first substrate transfer device, and
the sputter device is connected to the first substrate transfer device at a position adjacent to the substrate mount chamber.

7. The manufacturing apparatus according to claim 1, further comprising:
a first gate valve provided between the substrate mount chamber and the second substrate transfer device;
a second gate valve provided between the second substrate transfer device and the oxidation device; and
a control unit, wherein
the control unit confirms that the first gate valve is closed after completion of an oxidation process on the substrate in the oxidation device, and opens the second gate valve in a state where the first gate valve is closed.

8. The manufacturing apparatus according to claim 7, wherein
while any one of the first gate valve and the second gate valve is opened, the control unit keeps the other one of the first gate valve and the second gate valve from being opened.

9. The manufacturing apparatus according to claim 1, wherein
at least one of the plurality of substrate process devices connected to the second substrate transfer is a sputtering device, and
a component member containing a substance having a gettering effect for an oxygen gas is provided inside the sputtering device.

10. The manufacturing apparatus according to claim 1, wherein
at least one of the plurality of substrate process devices connected to the second substrate transfer is a sputtering device, and
an RF cathode is provided inside the sputtering device.

11. The manufacturing apparatus according to claim 9, wherein
the substance having the get tearing effect for oxygen is Ti or Ta.

12. The manufacturing apparatus according to claim 1, wherein
a vacuum level inside the second substrate transfer device is higher than a vacuum level inside the first substrate transfer device.

13. The manufacturing apparatus according to claim 1, wherein
at least one of the plurality of substrate process devices connected to the second substrate transfer is a heat treatment device.

14. The manufacturing apparatus according to claim 1, wherein
the first substrate transfer device includes two or more transfer means for transferring a substrate,
the second substrate transfer device includes at least one transfer means for transferring a substrate.
